(19) United States
(12) Patent Application Publication
(10) Pub. No.: US 2007/0170542 A1
(43) Pub. Date: Jul. 26, 2007

(54) Method of filling a high aspect ratio trench isolation region and resulting structure

(75) Inventor: Garo Derderian, Boise, ID (US)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/339,565

(22) Filed: Jan. 26, 2006

(51) Int. Cl. H01L 29/00; H01L 21/76

(52) U.S. Cl. 257/510; 257/520; 438/429; 438/435

(57) ABSTRACT

A method of filling a high aspect ratio trench isolation region, which allows for better gap-fill characteristics and avoids voids and seams in the isolation region. The method includes the steps of forming a trench, forming an oxide layer on the bottom and sidewalls of the trench, etching the oxide layer to expose the bottom of the trench, providing an epitaxial silicon layer on the bottom of the trench, and providing a high quality oxide chemical vapor deposition layer over the epitaxial silicon layer.

### FIELD OF THE INVENTION

The present invention relates to the field of semiconductor devices and, in particular, to a method for filling high aspect ratio trench isolation regions in semiconductor devices and the resulting structure.

### BACKGROUND OF THE INVENTION

Typically in semiconductor device applications, numerous devices are packed into a small area of a semiconductor substrate to create an integrated circuit. Generally, these devices need to be electrically isolated from one another to avoid problems among the devices. Accordingly, electrical isolation is an important part of semiconductor device design to prevent unwanted electrical coupling between adjacent components and devices. This is particularly true for high density memory, including but not limited to, flash memory.

Shallow trench isolation (STI) is one conventional isolation method. Shallow trench isolation provides very good device-to-device isolation. A shallow trench isolation process generally includes the following steps. First, a trench is formed in a semiconductor substrate using wet or dry etching with a mask. Then, an insulating layer is deposited on the entire surface of the semiconductor substrate to fill the trench. Finally, chemical mechanical polishing (CMP) is used to planarize the insulating layer. The insulating layer remaining in the trench acts as an STI region for providing isolation among devices in the substrate. Additionally, a nitride or oxidation layer may be formed on the sidewalls and bottom of the trench before depositing the insulating layer.

As semiconductor devices get smaller and more complex and packing density increases, the width of the STI regions also decreases. In addition, for certain types of electronic devices, a deeper isolation trench is desired. This leads to trench isolation regions with high aspect ratios; aspect ratio refers to the height of the trench compared to its width (h:w). An aspect ratio of greater than or equal to about 3:1 would be considered a high aspect ratio. When filling a high aspect ratio trench, and even when filling a less than high aspect ratio trench, with a high-density plasma oxide having good filling capability, voids or seams may still exist in the isolation regions. These defects cause electrical isolation between the devices to be reduced. Poor isolation can lead to short circuits and can reduce the lifetime of one or more circuits formed on a substrate.

FIGS. 1A and 1B illustrate high aspect ratio isolation trenches 11 formed in a semiconductor substrate 10 in accordance with the prior art. Before forming the isolation trench 11, other layers may be blanket deposited over the semiconductor substrate 10, for example, layers later used to form a gate structure, including an oxide layer 12, a polysilicon layer 14, and a nitride layer 16. After a trench 11 is formed through layers 12, 14, 15 and into substrate 10, an insulating layer 20 is deposited over the semiconductor substrate 10 to fill the trench 11. The insulating layer 20 can be deposited using high-density plasma chemical vapor deposition (HPDCVD) or any other high quality CVD oxide. Due to the high aspect ratio of the trench 11, the HPDCVD process may leave void regions 22 or seams 24 in the insulating layer 20, as shown in FIGS. 1A and 1B, respectively. Additionally, filling the high aspect ratio trench 11 requires that the HDP plasma bias be increased. This can lead to damage to the substrate 10 or to the oxide layer 12 or the polysilicon layer 14. Reducing the aspect ratio of the trench 11 allows running a lower bias (lower power) process thereby causing less damage.

Voids 22 occur because in the process of depositing the insulating layer 20, the insulating layer 20 on the sidewalls at the top of the trench 11 grows thicker than the portion closer to the bottom of the trench 11. Therefore, the opening at the top of the trench 11 becomes closed-off before the entire volume of the trench 11 can be filled, causing the void region 22 which diminishes the isolation properties of the filled trench 11.

Seams 24 occur where the opposing faces of the inward growing insulating layer 20 within the trench 11 are joined together. While seam 24, in and of itself, does no harm in the structure, if the structure of FIG. 1B is exposed to etching steps during subsequent processing, the portion of insulating layer 20 adjacent to seam 24 may be more sensitive to etching than the rest of material 20, which will reduce the isolation properties of the filled trench 11 in a similar manner to that of void 22.

Accordingly, there is a need and desire for a method of filling a high aspect ratio trench isolation region that achieves good isolation, but also reduces voids and seams in the insulating material.

### BRIEF SUMMARY OF THE INVENTION

The invention provides a method of filling a high aspect ratio trench isolation region and the resulting structure, where the method allows for better gap-fill characteristics while mitigating voids and seams in the isolation region. The method includes the steps of forming a trench, forming an oxide layer on the bottom and sidewalls of the trench, etching the oxide layer to expose the bottom of the trench, providing an epitaxial silicon layer on the bottom of the trench, and providing a high quality CVD oxide layer on the epitaxial silicon layer.

These and other features of the invention will be more apparent from the following detailed description that is provided in connection with the accompanying drawings and illustrated exemplary embodiments of the invention.

### BRIEF DESCRIPTION OF THE DRAWINGS

The above described features of the invention will be more clearly understood from the following detailed description, which is provided with reference to the accompanying drawings in which:

FIG. 1A depicts a prior art semiconductor substrate including a high aspect ratio isolation trench including a void.

FIG. 1B depicts a prior art semiconductor substrate including a high aspect ratio isolation trench including a seam.

FIG. 2 is a view of a semiconductor device with a high aspect ratio trench formed in a semiconductor substrate at a first stage of processing, in accordance with the present invention.

FIG. 3A is a view of the FIG. 2 semiconductor device at a processing stage subsequent to FIG. 2, in accordance with a first exemplary embodiment of the invention.

FIG. 3B is a view of the FIG. 2 semiconductor device at a processing stage subsequent to FIG. 2, in accordance with a second exemplary embodiment of the invention.

FIG. 4A is a view of the FIG. 3A semiconductor device at a processing stage subsequent to FIG. 3A, in accordance with the first exemplary embodiment of the invention.

FIG. 4B is a view of the FIG. 3B semiconductor device at a processing stage subsequent to FIG. 3B, in accordance with the second exemplary embodiment of the invention.

FIG. 5A is a view of the FIG. 4A semiconductor device at a processing stage subsequent to FIG. 4A, in accordance with the first exemplary embodiment of the invention.

FIG. 5B is a view of the FIG. 4B semiconductor device at a processing stage subsequent to FIG. 4B, in accordance with the second exemplary embodiment of the invention.

FIG. 6A is a view of the FIG. 5A semiconductor device at a processing stage subsequent to FIG. 5A, in accordance with the first exemplary embodiment of the invention.

FIG. 6B is a view of the FIG. 5B semiconductor device at a processing stage subsequent to FIG. 5B, in accordance with the second exemplary embodiment of the invention.

FIG. 7A is a view of the FIG. 6A semiconductor device at a processing stage subsequent to FIG. 6A, in accordance with the first exemplary embodiment of the invention.

FIG. 7B is a view of the FIG. 6B semiconductor device at a processing stage subsequent to FIG. 6B, in accordance with the second exemplary embodiment of the invention.

FIG. 8A is a view of a portion of a memory cell device according to another exemplary embodiment of the invention.

FIG. 8B is a view of a portion of a memory cell device according to yet another exemplary embodiment of the invention.

FIG. 9 is a view of the structure of a memory array in a conventional NAND type flash memory.

FIG. 10 is a block diagram of a computer system using a memory cell device with shallow trench isolation regions formed by the method of FIGS. 2-7B.

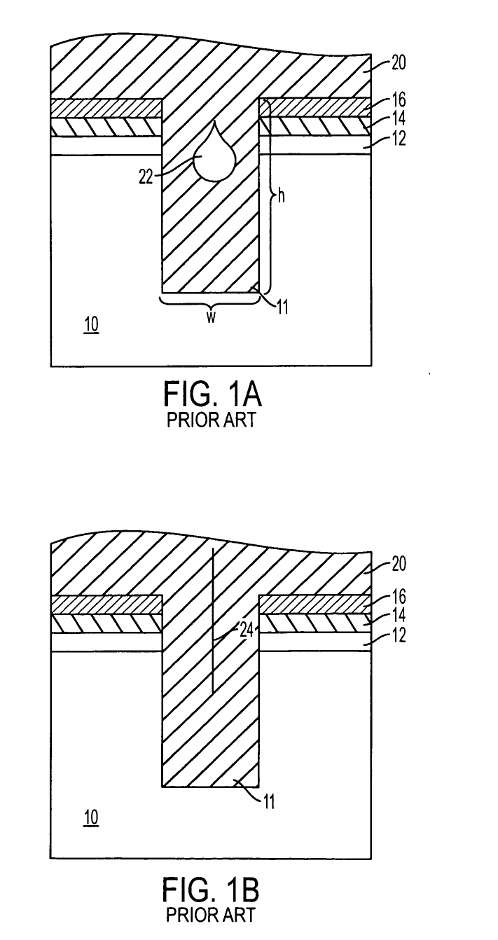

### DETAILED DESCRIPTION OF THE INVENTION

In the following detailed description, reference is made to the accompanying drawings, which form a part hereof and show by way of illustration specific embodiments in which the invention may be practiced. These embodiments are described in sufficient detail to enable those skilled in the art to practice the invention, and it is to be understood that other embodiments may be utilized, and that changes may be made without departing from the spirit and scope of the present invention. The progression of processing steps described is exemplary of embodiments of the invention; however, the sequence of steps is not limited to that set forth herein and may be changed as is known in the art, with the exception of steps necessarily occurring in a certain order

The present invention relates to a method of filling a high aspect ratio trench isolation region that allows for better gap-fill characteristics while substantially mitigating the presence of voids and seams. The invention may be used an any integrated circuit high packing density environment, including but not limited to memory, flash memory being but one example.

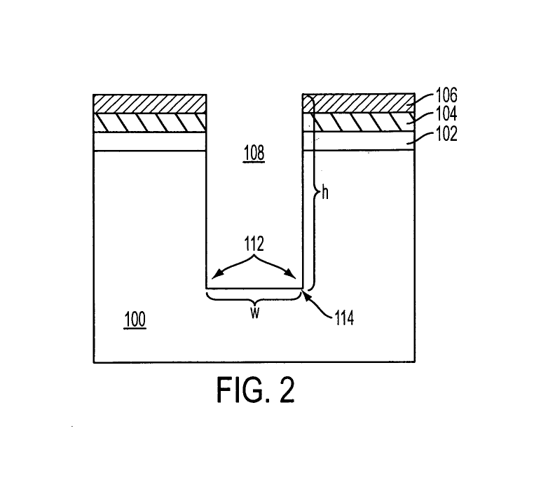

FIG. 2 depicts an unfilled high aspect ratio trench 108 to be used as an isolation region in a semiconductor substrate 100. Before forming the trench 108, an oxide layer 102, a polysilicon layer 104 and a nitride layer 106 may be blanket deposited over the semiconductor substrate 100 as a part of the later fabrication of devices in and over substrate 100. The high aspect ratio isolation trench 108 is formed by any method known in the art that is suitable for forming a high aspect ratio trench 108. The trench 108 has sidewalls 112 terminating at a bottom 114. The height h and the width w of the trench 108 are also shown. These values are used to define the aspect ratio of the trench 108.

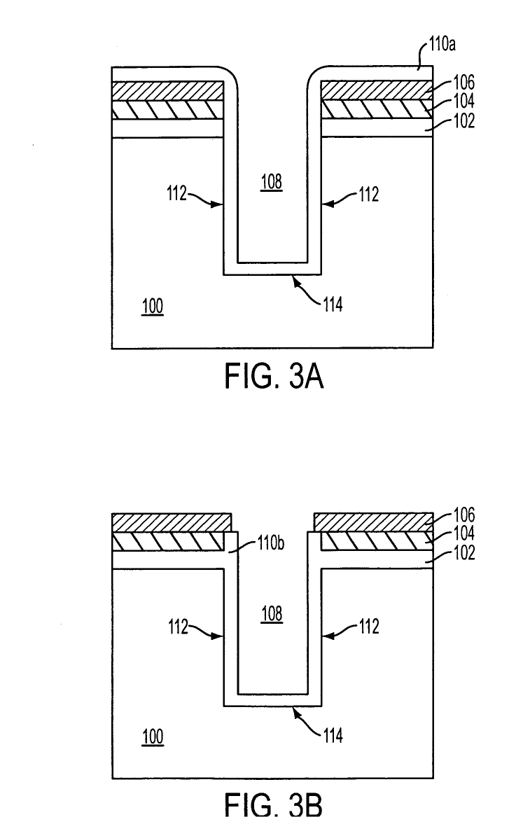

Referring to FIG. 3A, oxide layer 110a is formed on the sidewalls 112 and bottom 114 of the isolation trench 108. FIG. 3A shows the resultant oxide layer 110a from a deposition process. FIG. 3B shows an alternative embodiment where an oxide layer 110b is grown from the trench sidewalls 112 and bottom 114 using a thermal oxidation process. As can be seen, the FIG. 3B oxide layer 110b stops below the nitride layer 106 whereas the FIG. 3A oxide layer 110a covers the nitride layer 106. Alternatively, both deposition and oxidation may be employed to form the oxide layers 110a, 110b.

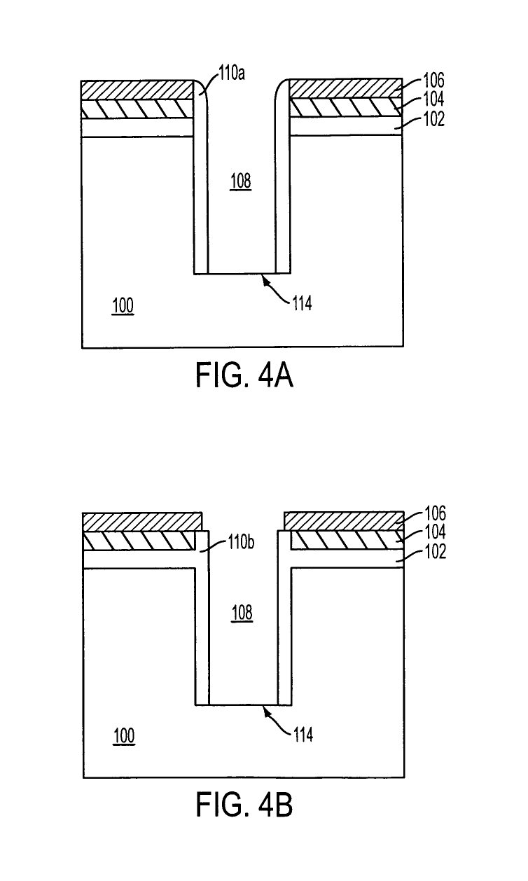

Next, a selective etching process is used on the oxide of the FIG. 3A or FIG. 3B structure to remove the oxide layers 110a and 110b, respectively, from the bottom 114 of the isolation trench 108, as shown in FIGS. 4A and 4B. In the embodiment of FIG. 4A, the etching process also removes the oxide layer 110a from over the nitride layer 106. Any etching method known in the art may be used. Alternatively, other processing techniques may be used such that the oxide layer 110a or 110b may be formed only on the sidewalls 112 of the isolation trench 108, thereby avoiding the etching requirement.

After the oxide layer 110a or 110b is removed from the bottom 114 of the isolation trench 108, a hydrogen fluoride (HF) cleaning process is used to prepare the bottom 114 of the isolation trench 108 for the growth of epitaxial silicon (epi silicon). Any other cleaning process known in the art may be used as well.

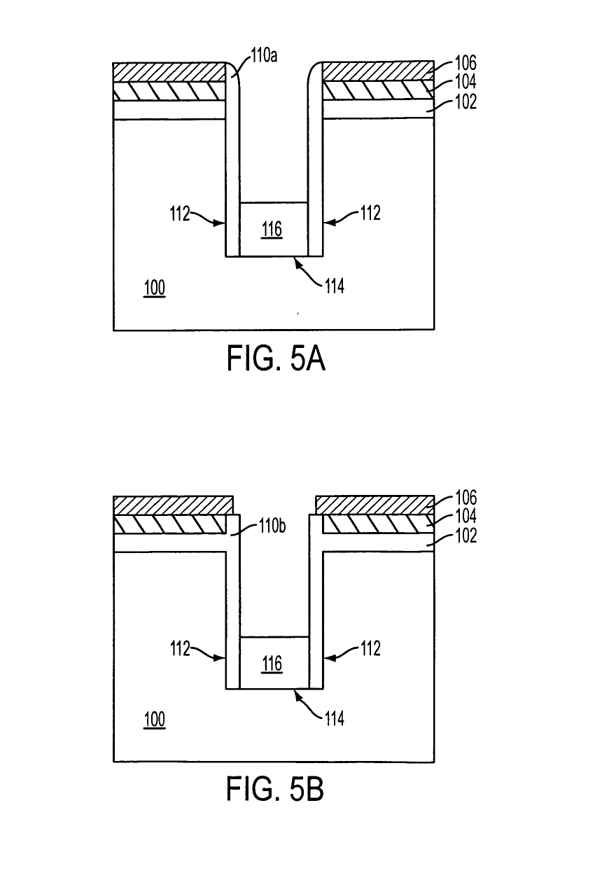

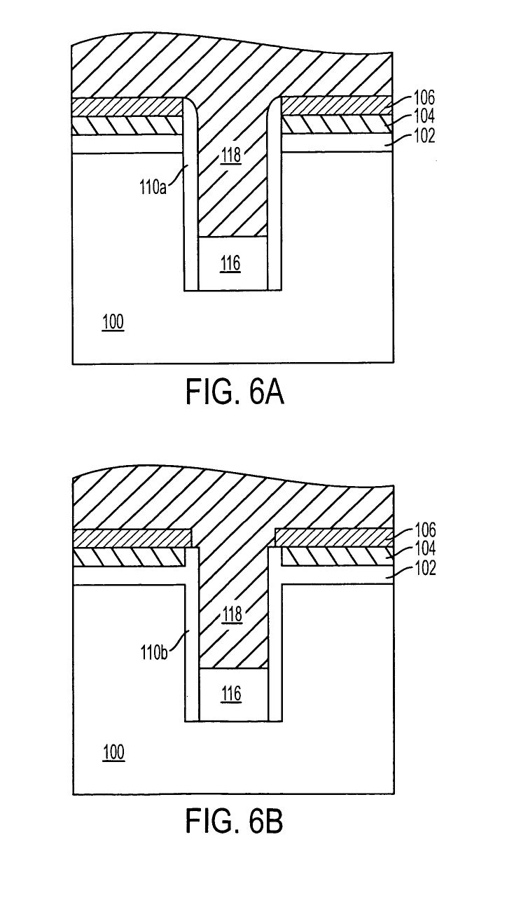

Once the bottom 114 of the isolation trench 108 has been cleaned, a layer of epi silicon 116 is grown from the bottom 114 of the isolation trench 108, as shown in FIGS. 5A and 5B. The epi silicon layer 116 is grown to a height which is less than the height of the sidewalls 112 of the isolation trench 108. More specifically, the height h of the epi silicon layer 116 should be no higher than the width w of the trench 108. This allows room in the isolation trench 108 for a deposition of the oxide layer 118 (FIGS. 6A and 6B). Growing this epi silicon layer 116 at the bottom 114 of the isolation trench 108 has the effect of reducing the aspect ratio of the isolation trench 108 for the HDP deposition process, while still allowing the isolation trench 108 to be deep enough to prevent lateral charge leakage and to maintain proper electrical isolation. Proper electrical isolation is maintained because the electrical field decreases while moving further from the oxide layer 102. Therefore, less electrical isolation is needed deeper in the trench 108 than near the top of the trench 108. The epi silicon layer 116 is a space holder between the oxide layer 110a, 110b on the two sidewalls 112. Additionally, the epi silicon layer 116 is a high quality material that will not trap electrical charge.

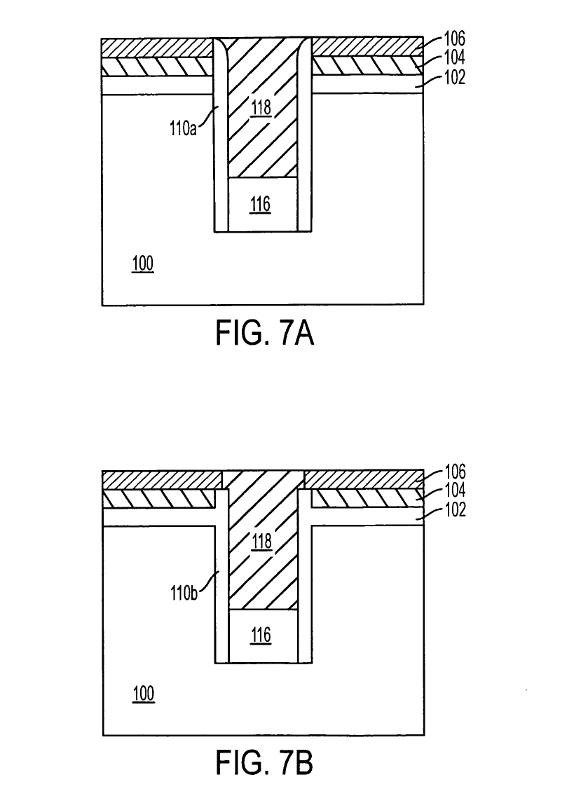

After the growth of the epi silicon layer 116, an oxide layer 118 is deposited over the semiconductor substrate 100 to fill the isolation trench 108, as shown in FIGS. 6A and 6B. The oxide layer 118 is high density plasma oxide in the preferred embodiment, but may also comprise any other high quality CVD oxide such as high temperature oxide (HTO), ozon-TEOS, or any other comparable oxide known in the art. The oxide layer 118 is deposited by a chemical vapor deposition (HDPCVD) process in the preferred embodiment, but may alternatively be done by any other method known in the art. The oxide layer 118 does not have any voids or gaps (such as those present in the prior art oxide layer) because the aspect ratio of the trench is reduced by the epi silicon layer 116 before the deposition of the oxide layer 118. As shown in FIGS. 7A and 7B, the oxide layer 118 is subsequently planarized to complete the filling of the isolation trench 108. This can be done by chemical mechanical polishing or by any method known in the art.

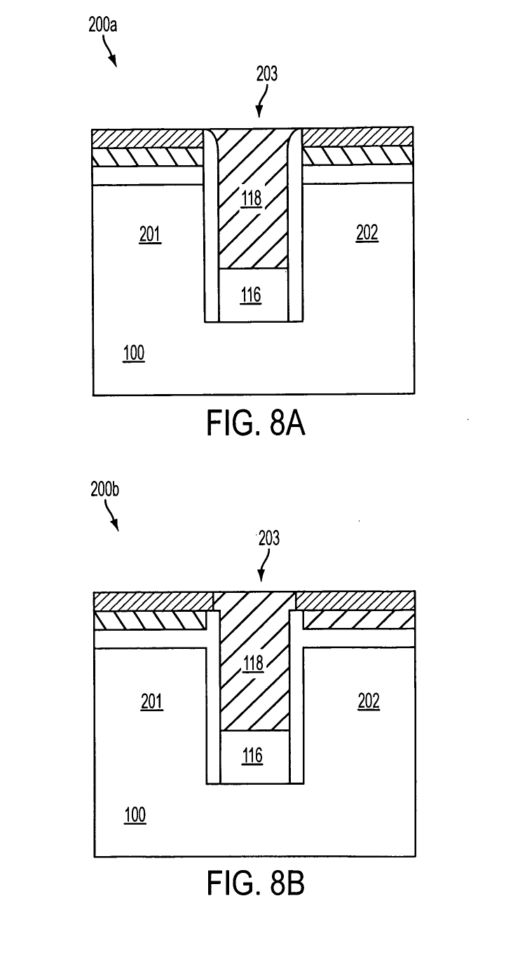

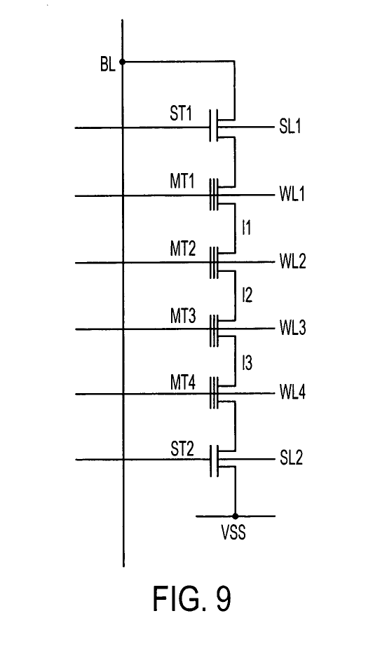

The trench isolation region formed by the method of the present invention may be incorporated to separate actual regions of an integrated circuit, for example, adjacent memory cell regions 201 and 202 of a flash memory structure 200a and 200b, as shown in FIGS. 8A and 8B. The trench isolation region 203, comprised of an epi silicon layer 116 and an oxide layer 118 (formed as described above), is between a first active region 201 and a second active region 202 in substrate 100 respectively associated with memory cells of the flash memory structure 200a or 200b. For example, FIG. 9, depicts a NAND type flash memory comprising four memory cells MT1, MT2, MT3, and MT4 connected to one NAND string connected to one bit line BL. The trench isolation region 203 of FIGS. 8A and 8B, may be formed between any two of the memory cells MT1, MT2, MT3, and MT4 at locations I1, I2, and/or I3 to electrically isolate the memory cells from each other. The actual flash memory cells formed in regions 201 and 202 may be of any conventional construction. However, the invention is not limited to flash memory and can be used in any integrated circuit device where isolation is required.

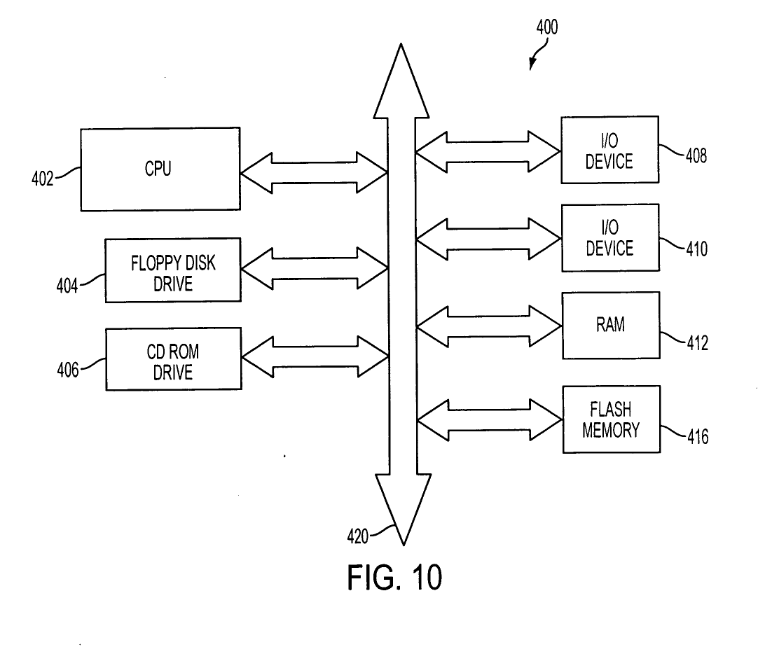

FIG. 10 is a block diagram of a processor system 400 utilizing a memory device 416, e.g., a flash memory device, constructed in accordance with the present invention. That is, the memory device 416 has cells separated by a trench isolation region constructed in accordance with the invention. The processor system 400 may be a computer system, a process control system or any other system employing a processor and associated memory. The system 400 includes a central processing unit (CPU) 402, e.g., a microprocessor, that communicates with the flash memory 416 and an I/O device 408 over a bus 420. It must be noted that the bus 420 may be a series of buses and bridges commonly used in a processor system, but for convenience purposes only, the bus 420 has been illustrated as a single bus. A second I/O device 410 is illustrated, but is not necessary to practice the invention. The processor system 400 also includes random access memory (RAM) device 412 and may include a read-only memory (ROM) device (not shown), and peripheral devices such as a floppy disk drive 404 and a compact disk (CD) ROM drive 406 that also communicate with the CPU 402 over the bus 420 as is well known in the art.

The above description and drawings are only to be considered illustrative of exemplary embodiments which achieve the features and advantages of the invention. Although exemplary embodiments of the present invention have been described and illustrated herein, many modifications, even substitutions of materials, can be made without departing from the spirit or scope of the invention. Accordingly, the above description and accompanying drawings are only illustrative of exemplary embodiments that can achieve the features and advantages of the present invention. It is not intended that the invention be limited to the embodiments shown and described in detail herein. The invention is limited only by the scope of the appended claims.

What is claimed as new and desired to be protected by Letters Patent of the United States is:

1. A method of forming a trench isolation region comprising:
forming a trench, having a first height, in a substrate;
forming a first oxide layer on the sidewalls of the trench;
forming an epitaxial layer on the bottom of the trench, the epitaxial layer having a second height less than the first height; and
forming a second oxide layer on the epitaxial layer.

2. The method of claim 1, wherein the act of forming the first oxide layer comprises:
forming an oxide layer on the bottom and sidewalls of the trench; and
etching the oxide layer to expose the bottom of the trench.

3. The method of claim 2, wherein the oxide layer on the bottom and sidewalls of the trench is formed by deposition.

4. The method of claim 2, wherein the oxide layer on the bottom and sidewalls of the trench layer is formed by oxidation.

5. The method of claim 1, wherein the epitaxial layer is formed by growing epitaxial silicon.

6. The method of claim 1, wherein the second height is less than or equal to a width of the trench.

7. The method of claim 1, wherein the second oxide layer comprises one of a high density plasma oxide, a high temperature oxide, and an ozone-TEOS.

8. The method of claim 7, wherein the second oxide layer is formed by chemical vapor deposition.

9. The method of claim 1, further comprising planarizing the second oxide layer using chemical mechanical polishing.

10. The method of claim 1, further comprising:
forming an oxide layer over the substrate;
forming a polysilicon layer over the oxide layer; and
forming a nitride layer over the polysilicon layer, wherein the oxide, polysilicon and nitride layers are formed prior to forming the trench.

11. A trench isolation region comprising:
a first oxide layer on sidewalls of a trench, provided in a substrate;
an epitaxial layer on the bottom of the trench; and
a second oxide layer on the epitaxial layer.

12. The trench isolation region of claim 11, wherein the epitaxial layer comprises epitaxial silicon.

13. The trench isolation region of claim 11, wherein a height of the epitaxial layer is less than or equal to a width of the trench.

14. The trench isolation region of claim 11, wherein the second oxide layer comprises one of a high density plasma oxide, a high temperature oxide, and an ozone-TEOS.

15. The trench isolation region of claim 11, wherein the trench is formed in the substrate, the substrate having an oxide layer, a polysilicon layer, and a nitride layer over the substrate.

16. A memory device comprising:
a first active area in a substrate;
a second active area in the substrate; and
a trench isolation region between the first and second active areas, the trench isolation region comprising:
a first oxide layer on sidewalls of a trench, provided in a substrate;
an epitaxial layer on the bottom of the trench; and
a second oxide layer on the epitaxial layer.

17. The memory device of claim 16, wherein the epitaxial layer of the trench isolation region comprises epitaxial silicon.

18. The memory device of claim 16, wherein a height of the epitaxial layer is less than or equal to a width of the trench.

19. The memory device of claim 16, wherein the second oxide layer of the trench isolation region comprises one of a high density plasma oxide, a high temperature oxide, and an ozone-TEOS.

20. The memory device of claim 16, wherein the memory device is flash memory.

21. A system comprising:
a processor;
a memory device coupled to the processor and comprising:
a first active area in a substrate;
a second active area in the substrate; and
a trench isolation region between the first and second active areas, the trench isolation region comprising:
a first oxide layer on sidewalls of a trench, formed in a substrate;
an epitaxial layer on the bottom of the trench; and
a second oxide layer on the epitaxial layer.

22. The system of claim 21, wherein the epitaxial layer of the trench isolation region comprises epitaxial silicon.

23. The system of claim 21, wherein a height of the epitaxial layer is less than or equal to a width of the trench

24. The system of claim 21, wherein the second oxide layer of the trench isolation region comprises one of a high density plasma oxide, a high temperature oxide, and an ozone-TEOS.

25. The system of claim 21, wherein the memory device is flash memory.
